(19) United States
(12) Patent Application Publication
(10) Pub. No.: US 2020/0266319 A1
(43) Pub. Date: Aug. 20, 2020

(54) DRIVING BACKPLANE, METHOD FOR PRODUCING THE SAME, AND DISPLAY DEVICE

(71) Applicants: KUNSHAN NEW FLAT PANEL DISPLAY TECHNOLOGY CENTER CO., LTD., Kunshan (CN); KUNSHAN GO-VISIONOX OPTO-ELECTRONICS CO., LTD., Kunshan (CN)

(72) Inventors: Dong WEI, Kunshan (CN); Xiaolong YANG, Kunshan (CN); Rubo XING, Kunshan (CN); Jiantai WANG, Kunshan (CN); Xuna LI, Kunshan (CN); Huashan CHEN, Kunshan (CN)

(21) Appl. No.: 16/868,491

(22) Filed: May 6, 2020

Related U.S. Application Data
(63) Continuation of application No. PCT/CN2019/073266, filed on Jan. 25, 2019.

(30) Foreign Application Priority Data
Sep. 27, 2018 (CN) 201811133675.8

(51) Int. Cl. H01L 33/38; H01L 33/62; H01L 25/075; H01L 33/40; H01L 33/00

(52) U.S. Cl. CPC H01L 33/387; H01L 33/62; H01L 25/0753; H01L 2933/0066; H01L 33/005; H01L 2933/0016; H01L 33/40

(57) ABSTRACT

The present application discloses a driving backplane, a method for producing the same and a display device. The driving backplane includes: a substrate; a first insulating film layer disposed on the substrate and including a first region and a second region; an extended anode disposed on a side of the first region of the first insulating film layer, a height of the extended anode matching a height of a cathode of a light-emitting chip; and an extended cathode disposed on a side of the second region of the first insulating film layer, a height of the extended cathode matching a height of an anode of the light-emitting chip.

### CROSS REFERENCES TO RELATED APPLICATIONS

This application is a continuation application of international application PCT/CN2019/073266, titled “DRIVING BACKPLANE, METHOD FOR PRODUCING THE SAME, AND DISPLAY DEVICE”, filed on Jan. 25, 2019, which claims the priority benefit of Chinese patent application No. 201811133675.8, titled “DRIVING BACKPLANE AND METHOD FOR PRODUCING THE SAME, MICRO LED CHIP AND METHOD FOR PRODUCING THE SAME, AND DISPLAY DEVICE”, and filed on Sep. 27, 2018. The entireties of these applications are incorporated by reference herein for all purposes.

### TECHNICAL FIELD

The present application relates to the field of display technologies.

### BACKGROUND

A Micro-LED chip is a new type of display chip, which has characteristics of self-luminous, small size and light weight, high efficiency, high brightness, high resolution, short response time, and the like, and is increasingly applied in various display and lighting fields.

A Micro-LED chip includes two parts: a light-emitting chip and a driving backplane. Since the process of producing the light-emitting chip and the process of producing the driving backplane are not compatible, the light-emitting chip and the driving backplane need to be produced separately. After the light-emitting chip and the driving backplane are produced, the light-emitting chip needs to be electrically connected to the driving backplane, so that the driving backplane drives the light-emitting chip to emit light.

The electrical connections between the light-emitting chip and the driving backplane are usually achieved via a flip-chip bonding process, that is, electrodes of the light-emitting chip are opposite to electrodes of the driving backplane after solder is provided on the driving backplane, and the electrodes of the light-emitting chip are soldered together with the corresponding electrodes of the driving backplane, thereby achieving the electrical connections between the light-emitting chip and the driving backplane.

### SUMMARY

The present application provides a driving backplane, a method for producing a driving backplane, and a display device, which can effectively solder electrodes of the driving backplane and corresponding electrodes of the light-emitting chip.

The present application provides a driving backplane. The driving backplane includes: a substrate; a first insulating film layer disposed on the substrate, the first insulating film layer comprising a first region and a second region; an extended anode disposed on a side of the first region of the first insulating film layer, the side of the first region being away from the substrate, a height of the extended anode matching a height of a cathode of a light-emitting chip; and an extended cathode disposed on a side of the second region of the first insulating film layer, the side of the second region being away from the substrate, a height of the extended cathode matching a height of an anode of the light-emitting chip.

Optionally, a first preset height of the first region of the first insulating film layer matches the height of the cathode of the light-emitting chip, so that the height of the extended anode matches the height of the cathode of the light-emitting chip.

Optionally, a second preset height of the second region of the first insulating film layer matches the height of the anode of the light-emitting chip, so that the height of the extended cathode matches the height of the anode of the light-emitting chip.

Optionally, the driving backplane further includes: at least one second insulating film layer disposed on the side of the first region of the first insulating film layer, wherein the side of the first region is away from the substrate.

Optionally, the extended anode is disposed on a side of the second insulating film layer, and the side of the second insulating film layer is away from the first insulating film layer.

Optionally, a sum of a first preset height of the first region of the first insulating film layer and a third preset height of the second insulating film layer matches the height of the cathode of the light-emitting chip.

Optionally, the driving backplane further includes at least one second insulating film layer disposed on the side of the second region of the first insulating film layer, wherein the side of the second region is away from the substrate.

Optionally, the extended cathode is disposed on a side of the second insulating film layer, and the side of the second insulating film layer is away from the first insulating film layer.

Optionally, a sum of a second preset height of the second region of the first insulating film layer and a fourth preset height of the second insulating film layer matches the height of the anode of the light-emitting chip.

Optionally, a material of the first insulating film layer and the second insulating film layer comprises at least one of materials of silicon dioxide, silicon nitride, and polyimide.

Optionally, adjacent insulating film layers are made of different materials, and the insulating film layer is the first insulating film layer and/or the second insulating film layer.

Optionally, a material of the extended anode and a material of the extended cathode include at least one of materials of gold, aluminum, and copper.

The present application further provides a method for producing a driving backplane. The method for producing a driving backplane includes: providing a substrate; producing a first insulating film layer on the substrate, the first insulating film layer comprising a first region and a second region; producing an extended anode on a side of the first region of the first insulating film layer, wherein the side of the first region is away from the substrate, and a height of the extended anode matches a height of a cathode of a light-emitting chip; and producing an extended cathode on a side of the second region of the first insulating film layer, wherein the side of the second region is away from the substrate, and a height of the extended cathode matches a height of an anode of the light-emitting chip.

Optionally, the producing the extended anode on the side of the first region of the first insulating film layer includes: coating a photoresist layer on a side of the first insulating film layer, wherein the side of the first insulating film layer is away from the substrate; exposing the photoresist layer coated on the first region of the first insulating film layer by a first preset mask; and developing the exposed photoresist layer to obtain the extended anode.

Optionally, the producing the extended cathode on the side of the second region of the first insulating film layer includes: coating a photoresist layer on a side of the first insulating film layer, wherein the side of the first insulating film layer is away from the substrate; exposing the photoresist layer coated on the second region of the first insulating film layer by a second preset mask; and developing the exposed photoresist layer to obtain the extended cathode.

Optionally, the producing the extended anode on the side of the first region of the first insulating film layer includes: producing at least one second insulating film layer on the side of the first region of the first insulating film layer, wherein the side of the first region is away from the substrate; and producing the extended anode on a side of the second insulating film layer, wherein the side of the second insulating film layer is away from the first insulating film layer.

Optionally, the producing the extended cathode on the side of the second region of the first insulating film layer includes: producing at least one second insulating film layer on a side of the second region of the first insulating film layer, wherein the side of the second region is away from the substrate; and producing the extended cathode on a side of the second insulating film layer, wherein the side of the second insulating film layer is away from the first insulating film layer.

Optionally, the extended anode is produced on the first region of the first insulating film layer, and the extended cathode is produced on the second region of the first insulating film layer by an electrode patterning technology.

Optionally, the electrode patterning technology comprises at least one of technologies of lithography technology, printing technology, and nanoimprint lithography.

The present application further provides a display device including a driving backplane, and the driving backplane includes: a substrate; a first insulating film layer disposed on the substrate, the first insulating film layer comprising a first region and a second region; an extended anode disposed on a side of the first region of the first insulating film layer, the side of the first region being away from the substrate, a height of the extended anode matching a height of a cathode of a light-emitting chip; and an extended cathode disposed on a side of the second region of the first insulating film layer, the side of the second region being away from the substrate, a height of the extended cathode matching a height of an anode of the light-emitting chip.

In the embodiment of the present application, by providing the first insulating film layer on the substrate to adjust the heights of the electrodes of the driving backplane, the heights of the electrodes of the driving backplane can match the heights of the electrodes of the light-emitting chip, thus saving the process cost of adjusting the heights of the electrodes of the light-emitting chip, and achieving effective soldering between the electrodes of the driving backplane and the electrodes of the light-emitting chip. The driving backplane is provided with the first insulating film layer, and the extended anode and the extended cathode are disposed on the first insulating film layer, so that the heights of the electrodes of the driving backplane match the heights of the electrodes of the light-emitting chip, thus avoiding the risk of electrodes collapse during the soldering process due to excessively large heights of the electrodes themselves without necessarily increasing the heights of the electrodes themselves.

### BRIEF DESCRIPTION OF THE DRAWINGS

The following descriptions for the accompanying drawings are used to provide a further understanding of the present application and constitute a part of the present application. The schematic embodiments of the present application and the description thereof are used to explain the present application, but not intended to constitute any improper limitation to the present application.

FIG. 1 illustrates schematic diagrams of achieving electrical connections between a light-emitting chip and a driving backplane via a flip-chip bonding process;

FIG. 2 is a schematic cross-sectional view of a driving backplane according to an embodiment of the present application;

FIG. 3 illustrates schematic cross-sectional views of two driving backplanes according to some embodiments of the present application;

FIG. 4 illustrates top views of four driving backplanes according to some embodiments of the present application;

FIG. 5 is a schematic flow chart of a method for producing a driving backplane according to an embodiment of the present application;

FIG. 6 is a schematic flow chart of a method for producing a Micro-LED chip according to an embodiment of the present application.

### DETAILED DESCRIPTION OF THE EMBODIMENTS

In a process of producing a Micro-LED chip, since the processes of producing the light-emitting chip and the driving backplane included in the Micro-LED chip are not compatible, the light-emitting chip and the driving backplane need to be produced separately. After the light-emitting chip and the driving backplane are produced, the electrodes of the light-emitting chip are electrically connected to the corresponding electrodes of the driving backplane, so that the driving backplane drives the light-emitting chip to emit light.

Usually, the light-emitting chip and the driving backplane, which are included in the Micro-LED chip, are soldered via a flip-chip bonding process, so as to achieve electrical connections between the light-emitting chip and the driving backplane.

Due to a height difference between a cathode and an anode of the light-emitting chip, the electrodes of the light-emitting chip and the corresponding electrodes of the driving backplane cannot be effectively soldered, thus affecting the performance of the Micro-LED chip. In order to make the heights of the electrodes of the light-emitting chip match the heights of the electrodes of the driving backplane and achieve effective soldering, the heights of the electrodes in the light-emitting chip usually need to be adjusted, and then the light-emitting chip and the driving backplane are soldered.

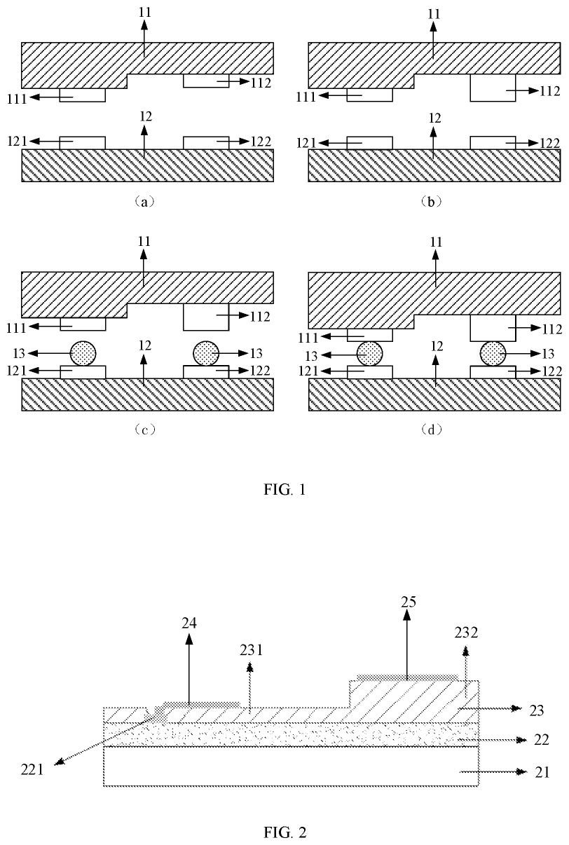

FIG. 1 illustrates schematic diagrams of achieving electrical connections between a light-emitting chip and a driving backplane via a flip-chip bonding process. As shown in FIG. 1 (a), there is a height difference between an electrode 111 and an electrode 112 of the light-emitting chip 11, so that heights of the electrodes 111 and 112 of the light-emitting chip 11 cannot match heights of electrodes 121 and 122 of the driving backplane 12. Therefore, before soldering the light-emitting chip 11 and the driving backplane 12, firstly, as shown in FIG. 1 (b), the height of the electrode 112 of the light-emitting chip 11 needs to be increased, so that the height of the electrode 111 and the height of the electrode 112 are the same; secondly, as shown in FIG. 1 (c), solder 13 is provided on the electrodes 121 and 122 of the driving backplane 12; finally, as shown in FIG. 1 (d), the light-emitting chip 11, of which the height of the electrode has been adjusted, is flipped, so that the electrode 111 of the light-emitting chip 11 is opposite to the electrode 121 of the driving backplane 12, and that the electrode 112 of the light-emitting chip 11 is opposite to the electrode 122 of the driving backplane 12; then the electrodes facing each other are soldered under a condition of high temperature and high pressure, to achieve electrical connections between the electrodes 111 and 112 of the light-emitting chip 11 and the corresponding electrodes 121 and 122 of the driving backplane 12.

However, increasing the heights of the electrodes of the light-emitting chip may cause an electrode collapse in the later soldering process, thus resulting in a failure to achieve effective soldering between the driving backplane and the light-emitting chip, and affecting the performance of the Micro-LED.

An embodiment of the present application provides a driving backplane, a method for producing the driving backplane, a Micro-LED chip, a method for producing the Micro-LED chip, and a display device, which can achieve effective soldering between the driving backplane and the light-emitting chip.

The light-emitting chip of an embodiment of the present application may be a Micro-LED light-emitting chip, and a plurality of electrodes (including an anode and a cathode) are arranged on a side of the light-emitting chip. The height of the anode and the height of the cathode of the light-emitting chip are different, that is, there is a certain height difference.

The technical solutions of the present application will be clearly and completely described below by making reference to the specific embodiments and the accompanying drawings. It is obvious that the embodiments to be described are only a part rather than all of the embodiments of the present application. All other embodiments obtained by persons skilled in the art based on the embodiments of the present disclosure without creative efforts shall fall within the protection scope of the present application.

The technical solutions provided by the embodiments of the present application will be described in detail below by making reference to the accompanying drawings.

In an embodiment of the present application, the driving backplane includes a substrate, a first insulating film layer, an extended anode, and an extended cathode. The first insulating film layer is disposed on the substrate, and includes a first region and a second region; the extended anode is disposed on a side of the first region of the first insulating film layer, wherein the side of the first region is away from the substrate; a height of the extended anode matches a height of a cathode of a light-emitting chip; the extended cathode is disposed on a side of the second region of the first insulating film layer, wherein the side of the second region is away from the substrate; and a height of the extended cathode matches a height of an anode of the light-emitting chip. The height of the extended anode/extended cathode is the height of the extended anode/extended cathode relative to a side of the substrate away from the first insulating film layer.

In an embodiment of the present application, the substrate can be a TFT (Thin Film Transistor) backplane.

FIG. 2 is a schematic cross-sectional view of a driving backplane according to an embodiment of the present application.

As shown in FIG. 2, the driving backplane includes a substrate 21 and a driving circuit layer 22. The driving circuit layer 22 is disposed on the substrate 21. An anode 221 is disposed on a side of the driving circuit layer 22 away from the substrate 21. A first insulating film layer 23 is disposed on the side of the driving circuit layer 22 away from the substrate 21. The first insulating film layer 23 includes a first region 231 and a second region 232.

A height of the first region 231 of the first insulating film layer 23 is a first preset height. The first preset height matches a height of a cathode of a light-emitting chip, and the cathode of the light-emitting chip needs to be electrically connected to the driving backplane. An extended anode 24 obtained by extending the anode 221 is disposed on a side of the first region 231 of the first insulating film layer 23, wherein the side of the first region 231 is away from the substrate 21. Since the height of the first region 231 of the first insulating film layer 23 matches the height of the cathode of the light-emitting chip, a height of the extended anode 24 on the first region 231 of the first insulating film layer 23 also matches the height of the cathode of the light-emitting chip.

A height of the second region 232 of the first insulating film layer 23 is a second preset height. The second preset height matches a height of an anode of the light-emitting chip, and the anode of the light-emitting chip needs to be electrically connected to the driving backplane. An extended cathode 25 is disposed on a side of the second region 232 of the first insulating film layer 23, wherein the side of the second region 232 is away from the substrate 21. Since the height of the second region 232 of the first insulating film layer 23 matches the height of the anode of the light-emitting chip, a height of the extended cathode 25 on the second region 232 of the first insulating film layer 23 also matches the height of the anode of the light-emitting chip.

In an embodiment of the present application, a material of the extended anode and a material of the extended cathode can include at least one of the following materials: gold, aluminum, copper, and the like.

The material of the extended anode and the material of the extended cathode can be one or more materials selected from the above described gold, aluminum, and copper. The material of the extended anode and the material of the extended cathode can also be other metals. The material of the extended anode and the material of the extended cathode can be the same or different.

In practical applications, there can be a larger height difference between different electrodes of the light-emitting chip. In order to make the heights of the electrodes of the driving backplane match the heights of the electrodes of the light-emitting chip, the height of the first region and/or the second region of the first insulating film layer of the driving backplane can be relatively large. When there is a larger height difference between different electrodes of the light-emitting chip, the driving backplane can be provided with a plurality of insulating film layers. In the structure of the plurality of insulating film layers, the height of each of the insulating film layers can be appropriately set, so that the problem of the insulating film layer cracking due to excessive large height of the insulating film layer will not easily occur.

In an embodiment of the present application, the driving backplane can further includes at least one second insulating film layer disposed on the side of the first region of the first insulating film layer, wherein the side of the first region is away from the substrate. In an embodiment of the present application, the extended anode is disposed on a side of the second insulating film layer, wherein the side of the second insulating film layer is away from the first insulating film layer.

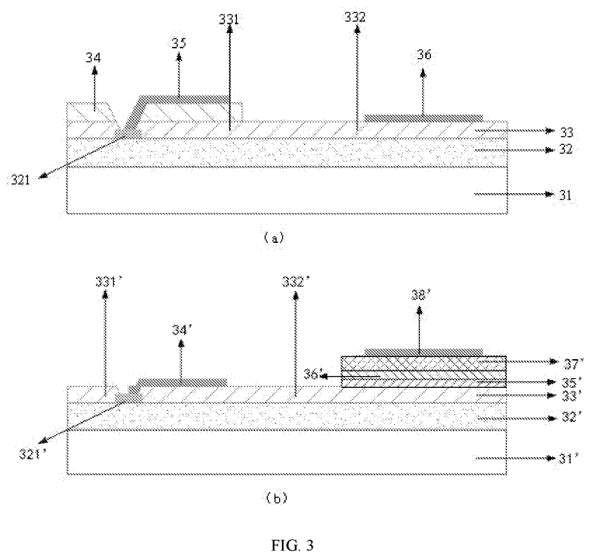

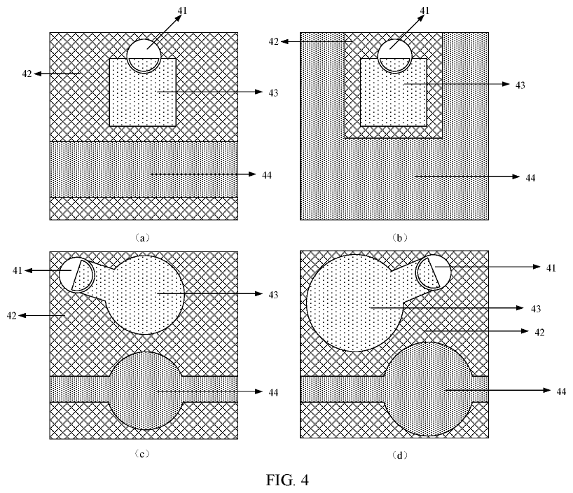

FIG. 3 illustrates schematic cross-sectional views of two driving backplanes according to some embodiments of the present application.

As shown in FIG. 3 (a), the driving backplane includes a substrate 31 and a driving circuit layer 32. The driving circuit layer 32 is disposed on the substrate 31. An anode 321 is disposed on a side of the driving circuit layer 32, wherein the side of the driving circuit layer 32 is away from the substrate 31. A first insulating film layer 33 is disposed on the side of the driving circuit layer 32, wherein the side of the driving circuit layer 32 is away from the substrate 31. The first insulating film layer 33 includes a first region 331 and a second region 332.

A height of the first region 331 of the first insulating film layer 33 is a first preset height. A second insulating film layer 34 is disposed on a side of the first region 331 of the first insulating film layer 33, wherein the side of the first region 331 is away from the substrate 31. A height of a second insulating film layer 34 is a third preset height. A sum of the first preset height and the third preset height matches a height of a cathode of a light-emitting chip, and the cathode of the light-emitting chip needs to be electrically connected to the driving backplane.

An extended anode 35 obtained by extending the anode 321 is disposed on a side of the second insulating film layer 34, wherein the side of the second insulating film layer 34 is away from the substrate 31. Since the sum of the height of the first region 331 of the first insulating film layer 33 and the height of the second insulating layer 34 matches the height of the cathode of the light-emitting chip, a height of the extended anode 35 on the second insulating film layer 34 also matches the height of the cathode of the light-emitting chip.

A height of the second region 332 of the first insulating film layer 33 is a second preset height. The second preset height matches a height of an anode of the light-emitting chip, and the anode of the light-emitting chip needs to be electrically connected to the driving backplane. An extended cathode 36 is disposed on a side of the second region 332 of the first insulating film layer 33, wherein the side of the second region 332 is away from the substrate 31. Since the height of the second region 332 of the first insulating film layer 33 matches the height of the anode of the light-emitting chip, a height of the extended cathode 36 on the second region 332 of the first insulating film layer 33 also matches the height of the anode of the light-emitting chip.

In an embodiment of the present application, at least one second insulating film layer of the driving backplane can be disposed on the side of the second region of the first insulating film layer, wherein the side of the second region is away from the substrate. In an embodiment of the present application, the extended cathode is disposed on a side of the second insulating film layer, wherein the side of the second insulating film layer is away from the first insulating film layer.

Still taking FIG. 3 as an example, as shown in FIG. 3 (b), the driving backplane includes a substrate 31′ and a driving circuit layer 32′. The driving circuit layer 32′ is disposed on the substrate 31′. An anode 321′ is disposed on a side of the driving circuit layer 32′, wherein the side of the driving circuit layer 32′ is away from the substrate 31′. A first insulating film layer 33′ is disposed on a side of the driving circuit layer 32′, wherein the side of the driving circuit layer 32′ is away from the substrate 31′. The first insulating film layer 33′ includes a first region 331′ and a second region 332′.

A height of the first region 331′ of the first insulating film layer 33′ is a first preset height. The first preset height matches a height of a cathode of a light-emitting chip, and the cathode of the light-emitting chip needs to be electrically connected to the driving backplane.

An extended anode 34′ obtained by extending the anode 321′ is disposed on a side of the first region 331′ of the first insulating film layer 33′, wherein the side of the first region 331′ is away from the substrate 31′. Since the height of the first region 331′ of the first insulating film layer 33′ matches the height of the cathode of the light-emitting chip, a height of the extended anode 34′ on the first region 331′ of the first insulating film layer 33′ also matches the height of the cathode of the light-emitting chip.

A height of the second region 332′ of the first insulating film layer 33′ is a second preset height. Three second insulating film layers 35′, 36′, and 37′ are disposed on a side of the second region 332′ of the first insulating film layer 33′, wherein the side of the second region 332′ is away from the substrate 31′. The three second insulating film layers 35′, 36′, and 37′ are sequentially provided layer by layer. A sum of heights of the second insulating film layers 35′, 36′, and 37′ is a fourth preset height. A sum of the second preset height and the fourth preset height matches a height of an anode of the light-emitting chip, and the anode of the light-emitting chip needs to be electrically connected to the driving backplane.

An extended cathode 38′ is disposed on a side of the second insulating film layer 37′ wherein the side of the second insulating film layer 37′ is away from the substrate 31′. Since a sum of the height of the second region 332′ of the first insulating film layer 33′ and the heights of three second insulating film layers 35′, 36′, and 37′ matches the height of the anode of the light-emitting chip, a height of the extended cathode 38′ on the second insulating film layer 37′ also matches the height of the anode of the light-emitting chip.

In an embodiment of the present application, a material of the first insulating film layer and a material of the second insulating film layer can include at least one of the following materials: silicon dioxide, silicon nitride, polyimide, and the like.

The material of the first insulating film layer and the material of the second insulating film layer can be one or more materials selected from silicon dioxide, silicon nitride, and polyimide. The material of the first insulating film layer and the material of the second insulating film layer can also be other insulating materials.

In an embodiment of the present application, adjacent insulating film layers can be made of different materials, so that the problem of the film layer cracking caused by excessively large height of a single insulating film layer will not easily occur. The insulating film layer can be the first insulating film layer and/or the second insulating film layer.

Since the extended anode and the extended cathode are disposed on the insulating film layer, the sizes of the extended anode and the extended cathode can be free from space restrictions, so that the extended anode and the extended cathode can be produced to be various shapes as required.

FIG. 4 illustrates top views of four driving backplanes according to some embodiments of the present application.

As shown in FIG. 4, the driving backplane includes an anode 41, an insulating layer 42, an extended anode 43, and an extended cathode 44 on a substrate.

As shown in FIGS. 4(a)-4(d), the extended anode 43 and the extended cathode 44 of various shapes and various sizes can be produced as required.

Heights of the electrodes of the driving backplane are adjusted, so that the heights of the electrodes of the driving backplane matches the heights of the electrodes of the light-emitting chip, thus saving the process cost of adjusting the heights of the electrodes of the light-emitting chip, and achieving effective soldering between the electrodes of the driving backplane and the electrodes of the light-emitting chip. The driving backplane is provided with the insulating film layer, and the extended anode and the extended cathode are provided on the insulating film layer, so that the heights of the electrodes of the driving backplane match the heights of the electrodes of the light-emitting chip, thus avoiding the risk of electrodes collapse during the soldering process due to excessively large heights of the electrodes themselves without necessarily increasing the heights of the electrodes themselves.

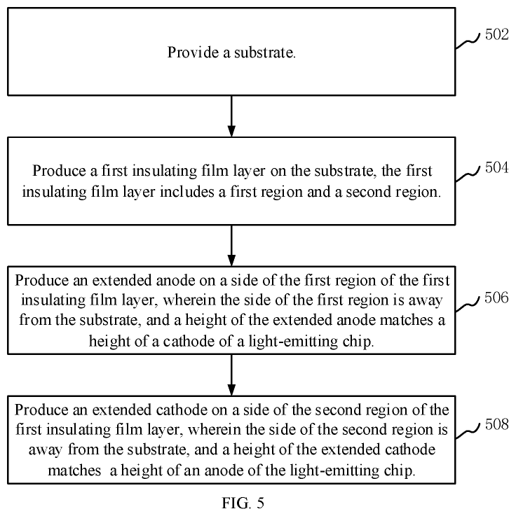

FIG. 5 is a schematic flow chart of a method for producing a driving backplane according to an embodiment of the present application. This method can be illustrated as follows.

At Step 502, provide a substrate.

In a process of producing the driving backplane, a substrate can be provided. In an embodiment of the present application, the substrate can be a TFT backplane.

At Step 504, produce a first insulating film layer on the substrate, wherein the first insulating film layer includes a first region and a second region.

At Step 506, produce an extended anode on a side of the first region of the first insulating film layer, wherein the side of the first region is away from the substrate, and a height of the extended anode matches a height of a cathode of a light-emitting chip.

The height of the extended anode is relative to a side of the substrate, wherein the side of the substrate away from the first insulating film layer.

At Step 508, produce an extended cathode on a side of the second region of the first insulating film layer, wherein the side of the second region is away from the substrate, and a height of the extended cathode matches a height of an anode of the light-emitting chip.

The height of the extended cathode is relative to the side of the substrate, wherein the side of the substrate is away from the first insulating film layer.

In order that the heights of the electrodes of the driving backplane match the heights of the electrodes of the light-emitting chip, the first insulating film layer is produced on the substrate. The height of the first region of the first insulating film layer matches the height of the cathode of the light-emitting chip, which makes the extended anode produced on the first region of the first insulating film layer also match the height of the cathode of the light-emitting chip. The height of the second region of the first insulating film layer matches the height of the anode of the light-emitting chip, which makes the extended cathode produced on the second region of the first insulating film layer also match the height of the anode of the light-emitting chip. It is achieved thereby that the heights of the electrodes of the driving backplane match the heights of the electrodes of the light-emitting chip.

In an embodiment of the present application, the extended anode can be produced on the first region of the first insulating film layer, and the extended cathode can be produced on the second region of the first insulating film layer by using an electrode patterning technology.

The electrode patterning technology can include at least one of the following technologies: lithography technology, printing technology, nanoimprint technology, and the like.

The electrode patterning technology may be one or more technologies selected from the above described lithography technology, printing technology, and nanoimprint technology. The electrode patterning technology can also be other patterning technologies.

In an embodiment of the present application, the extended anode and the extended cathode can be produced simultaneously by using a one-step electrode patterning technology, or the extended anode and the extended cathode can be produced separately by using a step-by-step electrode patterning technology.

The process of producing the extended anode and the extended cathode will be described in detail below by taking the lithography technology as an example.

Firstly, a photoresist layer can be coated on a side of the first insulating film layer, wherein the side of the first insulating film layer away from the substrate.

Secondly, the photoresist layer coated on the first region of the first insulating film layer is exposed by a first preset mask, and the photoresist layer coated on the second region of the first insulating film layer is exposed by a second preset mask.

The first preset mask and the second preset mask can be determined according to the actually required pattern shapes of the extended anode and the extended cathode and are not specifically limited herein.

Finally, the exposed photoresist layer is developed, to obtain the extended anode and the extended cathode. After being exposed, the photoresist layer is dissolved by developer, so that the extended anode is produced on the first region of the first insulating film layer, and the extended cathode is produced on the second region of the first insulating film layer.

The extended anode and the extended cathode can be produced simultaneously by using a one-step lithography technology by the first preset mask and the second preset mask, or the extended anode and the extended cathode can be produced separately by using a step-by-step lithography technology by the first preset mask and the second preset mask, which are not specifically limited herein.

In an embodiment of the present application, a material of the extended anode and a material of the extended cathode can be the material of the extended anode and the material of the extended cathode in any one of the foregoing embodiments, which will not be described herein again.

In practical applications, there may be a larger height difference between different electrodes of the light-emitting chip. In order that the heights of the electrodes of the driving backplane match the heights of the electrodes of the light-emitting chip, the height of the first region and/or the second region of the first insulating film layer of the driving backplane may be larger. When there is a larger height difference between different electrodes of the light-emitting chip, a plurality of insulating film layers can be provided in the driving backplane. In the structure of the plurality of insulation film layers, the height of each of the insulation film layers can be appropriately set, so that the problem of the insulation film layer cracking caused by excessive large height of the insulating film layer will not easily occur.

In an embodiment of the present application, the method for producing a driving backplane further includes: produce at least one second insulating film layer on the side of the first region of the first insulating film layer, wherein the side of the first region is away from the substrate; and produce the extended anode on a side of the second insulating film layer, wherein the side of the second insulating film layer is away from the first insulating film layer.

In an embodiment of the present application, the method for producing a driving backplane further includes: produce at least one second insulating film layer on the side of the second region of the first insulating film layer, wherein the side of the second region is away from the substrate; and produce the extended cathode on a side of the second insulating film layer, wherein the side of the second insulating film layer is away from the first insulating film layer.

In an embodiment of the present application, a material of the first insulating film layer and a material of the second insulating film layer can be the material of the first insulating film layer and the material of the second insulating film layer in any one of the foregoing embodiments, which will not be described herein again.

In an embodiment of the present application, adjacent insulating film layers can be made of different materials.

Since the extended anode and the extended cathode are produced on the insulating film layer, the size of the extended anode and the size of the extended cathode can be free from space restrictions, so that the extended anode and the extended cathode can be produced to be various shapes as required.

In the substrate provided in the embodiment of the present application, the first insulating film layer is provided on the substrate, so that the heights of the electrodes of the driving backplane can match the heights of the electrodes of the light-emitting chip, thereby achieving effective soldering between the driving backplane and the light-emitting chip.

An embodiment of the present application provides a Micro-LED chip. The Micro-LED chip includes: a light-emitting chip including an anode and a cathode; and a driving backplane including an extended anode and an extended cathode. The anode and the cathode of the light-emitting chip are connected to the extended cathode and the extended anode of the driving backplane by solder respectively. The driving backplane in this embodiment can be the driving backplane of any one of the foregoing embodiments.

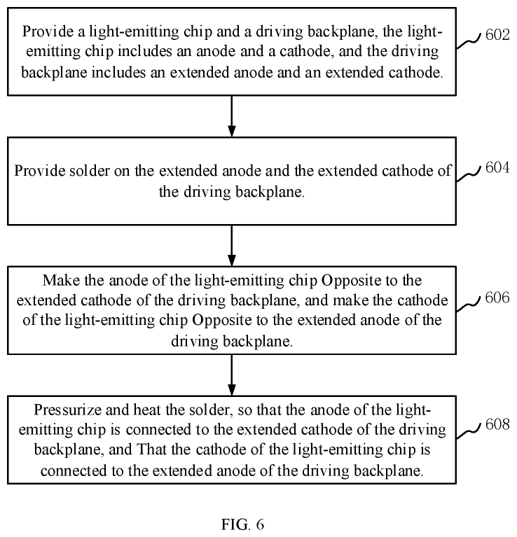

FIG. 6 is a schematic flow chart of a method for producing a Micro-LED chip according to an embodiment of the present application. The method for producing the Micro-LED chip can be illustrated as follows.

At Step 602: provide a light-emitting chip and a driving backplane, wherein the light-emitting chip includes an anode and a cathode, and the driving backplane includes an extended anode and an extended cathode.

At Step 604: provide solder on the extended anode and the extended cathode of the driving backplane.

At Step 606: make the anode of the light-emitting chip opposite to the extended cathode of the driving backplane, and make the cathode of the light-emitting chip opposite to the extended anode of the driving backplane.

At Step 608: pressurize and heat the solder, so that the anode of the light-emitting chip is connected to the extended cathode of the driving backplane, and that the cathode of the light-emitting chip is connected to the extended anode of the driving backplane.

As for any one of the driving backplanes illustrated in the embodiments of FIGS. 2 to 4 or the driving backplane produced according to the embodiment of FIG. 5, the heights of the electrodes of the driving backplane can match the heights of the electrodes of the light-emitting chip. Therefore, effective soldering between the driving backplane and the light-emitting chip can be achieved by the flip-chip bonding process.

An embodiment of the present disclosure further provides a display device. The display device can include the driving backplane described above or a driving backplane produced by the above described method for producing a driving backplane.

An embodiment of the present application further provides a display device. The display device may include the above described Micro-LED chip or a Micro-LED chip produced by the above described method for producing a Micro-LED chip.

The above embodiments merely illustrate several embodiments of the present application, and the description thereof is more specific and detailed, but it should not be understood to be limitations to the scope of the present application. For those skilled in the art, several variations and improvements may be made without departing from the concept of the present application, and these variations and improvements are all within the protection scope of the present application. Therefore, the protection scope of this application should be defined by the appended claims.

What is claimed is:

1. A driving backplane, comprising:
a substrate;
a first insulating film layer disposed on the substrate, the first insulating film layer comprising a first region and a second region;
an extended anode disposed on a side of the first region of the first insulating film layer, the side of the first region being away from the substrate, a height of the extended anode matching a height of a cathode of a light-emitting chip; and
an extended cathode disposed on a side of the second region of the first insulating film layer, the side of the second region being away from the substrate, a height of the extended cathode matching a height of an anode of the light-emitting chip.

2. The driving backplane of claim 1, wherein a first preset height of the first region of the first insulating film layer matches the height of the cathode of the light-emitting chip, so that the height of the extended anode matches the height of the cathode of the light-emitting chip.

3. The driving backplane of claim 1, wherein a second preset height of the second region of the first insulating film layer matches the height of the anode of the light-emitting chip, and the height of the extended cathode matches the height of the anode of the light-emitting chip.

4. The driving backplane of claim 1, further comprising:
at least a second insulating film layer disposed on the side of the first region of the first insulating film layer, wherein the side of the first region is away from the substrate.

5. The driving backplane of claim 4, wherein:
the extended anode is disposed on a side of the second insulating film layer, and the side of the second insulating film layer is away from the first insulating film layer.

6. The driving backplane of claim 5, wherein:
a sum of a first preset height of the first region of the first insulating film layer and a third preset height of the second insulating film layer matches the height of the cathode of the light-emitting chip.

7. The driving backplane of claim 1, further comprising:
at least one second insulating film layer disposed on the side of the second region of the first insulating film layer, wherein the side of the second region is away from the substrate.

8. The driving backplane of claim 7, wherein:
the extended cathode is disposed on a side of the second insulating film layer, and the side of the second insulating film layer is away from the first insulating film layer.

9. The driving backplane of claim 8, wherein:
a sum of a second preset height of the second region of the first insulating film layer and a fourth preset height of the second insulating film layer matches the height of the anode of the light-emitting chip.

10. The driving backplane of claim 4, wherein a material of the first insulating film layer and the second insulating film layer comprises at least one of materials of silicon dioxide, silicon nitride, and polyimide.

11. The driving backplane of claim 4, wherein adjacent insulating film layers are made of different materials, and the insulating film layer is the first insulating film layer and/or the second insulating film layer.

12. The driving backplane of claim 1, wherein a material of the extended anode and a material of the extended cathode comprises at least one of materials of gold, aluminum, and copper.

13. A method for producing a driving backplane, comprising:
providing a substrate;
producing a first insulating film layer on the substrate, the first insulating film layer comprising a first region and a second region;
producing an extended anode on a side of the first region of the first insulating film layer, wherein the side of the first region is away from the substrate, and a height of the extended anode matches a height of a cathode of a light-emitting chip; and
producing an extended cathode on a side of the second region of the first insulating film layer, wherein the side of the second region is away from the substrate, and a height of the extended cathode matches a height of an anode of the light-emitting chip.

14. The method for producing the driving backplane of claim 13, wherein the producing the extended anode on the side of the first region of the first insulating film layer comprises:
coating a photoresist layer on a side of the first insulating film layer, wherein the side of the first insulating film layer is away from the substrate;
exposing the photoresist layer coated on the first region of the first insulating film layer by a first preset mask; and
developing the exposed photoresist layer to obtain the extended anode.

15. The method for producing a driving backplane of claim 13, wherein the producing the extended cathode on the side of the second region of the first insulating film layer comprises:
coating a photoresist layer on a side of the first insulating film layer, wherein the side of the first insulating film layer is away from the substrate;
exposing the photoresist layer coated on the second region of the first insulating film layer by a second preset mask; and
developing the exposed photoresist layer to obtain the extended cathode.

16. The method for producing a driving backplane of claim 13, wherein the producing the extended anode on the side of the first region of the first insulating film layer comprises:
producing at least one second insulating film layer on the side of the first region of the first insulating film layer, wherein the side of the first region is away from the substrate; and producing the extended anode on a side of the second insulating film layer, wherein the side of the second insulating film layer is away from the first insulating film layer.

17. The method for producing a driving backplane of claim 13, wherein the producing the extended cathode on the side of the second region of the first insulating film layer comprises:
producing at least one second insulating film layer on a side of the second region of the first insulating film layer, wherein the side of the second region is away from the substrate; and producing the extended cathode on a side of the second insulating film layer, wherein the side of the second insulating film layer is away from the first insulating film layer.

18. The method for producing a driving backplane of claim 13, wherein:
the extended anode is produced on the first region of the first insulating film layer, and the extended cathode is produced on the second region of the first insulating film layer by an electrode patterning technology.

19. The method for producing a driving backplane of claim 18, wherein the electrode patterning technology comprises at least one of technologies of lithography technology, printing technology, and nanoimprint lithograhpy.

20. A display device, comprising a driving backplane, wherein the driving backplane comprises:
a substrate;
a first insulating film layer disposed on the substrate, the first insulating film layer comprising a first region and a second region;
an extended anode disposed on a side of the first region of the first insulating film layer, the side of the first region being away from the substrate, a height of the extended anode matching a height of a cathode of a light-emitting chip; and
an extended cathode disposed on a side of the second region of the first insulating film layer, the side of the second region being away from the substrate, a height of the extended cathode matching a height of an anode of the light-emitting chip.
